(19) United States
(12) Patent Application Publication
(10) Pub. No.: US 2025/0314688 A1
(43) Pub. Date: Oct. 9, 2025

(54) SINGLE-END TRAVELING WAVE FAULT LOCATION ESTIMATION AND RESULTS ORDERED USING A LOCAL OR REMOTE TERMINAL AS REFERENCE

(71) Applicant: Schweitzer Engineering Laboratories, Inc., Pullman, WA (US)

(72) Inventors: Armando Guzman-Casillas, Pullman, WA (US); Yajian Tong, Bellaire, TX (US); Johnny G. Sim, Pullman, WA (US)

(73) Assignee: Schweitzer Engineering Laboratories, Inc., Pullman, WA (US)

(21) Appl. No.: 19/169,906

(22) Filed: Apr. 3, 2025

Related U.S. Application Data
(60) Provisional application No. 63/574,403, filed on Apr. 4, 2024.

(51) Int. Cl. G01R 31/08; H02H 7/26

(52) U.S. Cl. CPC G01R 31/086; H02H 7/262

(57) ABSTRACT

Systems and methods for determining a location of a fault in a power delivery system are provided. Such a method may include receiving several single-end traveling wave fault location values and a single-end impedance fault location value based on measurements from a first intelligent electronic device at a local terminal. Based on a relationship between the single-end traveling wave fault location values, the single-end impedance fault location value, a location of the local terminal, and the location of the remote terminal, one of the several single-end traveling wave fault location values may be selected as a fault location value of highest confidence among the several single-end traveling wave fault location values.

### CROSS REFERENCE TO RELATED APPLICATIONS

This application claims benefit of U.S. Provisional Patent Application No. 63/574,403, filed on Apr. 4, 2024, and herein incorporated by reference in its entirety.

### BACKGROUND

This disclosure relates to locating faults in electrical power delivery systems. More particularly, this disclosure relates to determining a fault location in electrical power delivery systems based on single-end traveling wave fault location estimation according to a local terminal or a remote terminal as a reference.

Transmission line protection improves power system stability in power delivery systems. If faults are not cleared before the critical fault clearing time, the system may lose transient stability and possibly suffer a blackout. Accurate fault location of transmission line faults allows crews to make repairs and restore power quickly. Fault location is critical for improving power system reliability and is of great value to power system operators and transmission asset owners.

Traveling waves may be used to identify a fault location as the waves reflect at locations of changing impedance along the power delivery system. Traveling-wave-based fault location methods may offer accuracy in the order of one to two tower spans, independent of the line length. This accuracy makes finding fault locations comparatively less challenging and less time-consuming than other methods. Many faults are due to weakened insulators. Thus, when line patrols find and replace damaged insulators, recurrences of transient faults at the same locations are reduced or eliminated, which results in improved power system reliability.

Single-end traveling wave fault location methods use the time differences between the first arrived wave and the successive reflections from the fault and/or remote terminal to compute the fault location. This method is appealing because it uses local information available to a local terminal. There may be many potential answers provided by this method, however, and it may be difficult to discern which of the answers should be assigned the greatest confidence.

### BRIEF DESCRIPTION OF THE DRAWINGS

Various aspects of this disclosure may be better understood upon reading the following detailed description and upon reference to the drawings described below in which like numerals refer to like parts.

FIG. 1 is a block diagram of an electrical power delivery system with a local terminal L and a remote terminal R, with a fault on a conductor between terminals L and R, according to embodiments of the present disclosure;

FIG. 2 is a plot illustrating traveling waves of the fault received at the local terminal of the power delivery system of FIG. 1, according to embodiments of the current disclosure;

FIG. 3 is a plot illustrating traveling waves of electrical currents of FIG. 2, according to embodiments of the current disclosure, according to embodiments of the present disclosure;

FIG. 4 is a process flow diagram illustrating an embodiment of a process of selecting one or more potential fault locations among multiple potential fault locations that more accurately indicate a fault location along the conductor of the power delivery system of FIG. 1, according to embodiments of the present disclosure;

FIG. 5 is a process flow diagram illustrating an embodiment of a process 186 of determining whether to adjust the confidence level of the at least one potential fault location having the confidence level greater than the confidence threshold, according to embodiments of the present disclosure;

FIG. 6 is a process flow diagram illustrating an embodiment of a first process 188-1 of adjusting confidence levels of at least a portion of the potential fault locations based on whether the received traveling waves are reflected from the local terminal 112 or the remote terminal 114, according to embodiments of the present disclosure;

FIG. 7 is a process flow diagram illustrating an embodiment of a second process 188-2 of adjusting confidence levels of at least a portion of the potential fault locations based on current or voltage change magnitudes associated with the potential fault locations, according to embodiments of the present disclosure;

FIG. 8 is a process flow diagram illustrating an embodiment of a third process 188-3 of adjusting confidence levels of at least a portion of the potential fault locations based on predicting a number of subsequent traveling waves based on a first received traveling wave, according to embodiments of the present disclosure;

FIGS. 9A and 9B are a flowchart of a method for determining a confidence level of single-end traveling wave fault location values, according to embodiments of the present disclosure;

FIGS. 10A-10C are a flowchart of another method for determining a confidence level of single-end traveling wave fault location values, according to embodiments of the present disclosure; and

FIGS. 11A-11C are a flowchart of another method for determining a confidence level of single-end traveling wave fault location values, according to embodiments of the present disclosure.

### DETAILED DESCRIPTION

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the phrase A “based on” B is intended to mean that A is at least partially based on B. Moreover, unless expressly stated otherwise, the term “or” is intended to be inclusive (e.g., logical OR) and not exclusive (e.g., logical XOR). In other words, the phrase “A or B” is intended to mean A, B, or both A and B.

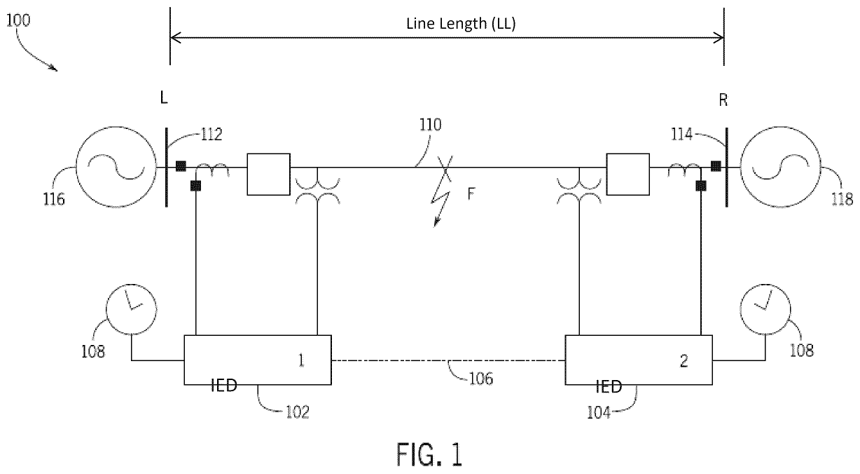

FIG. 1 illustrates a block diagram of a portion of a power delivery system 100 (e.g., an electrical power delivery system) for determining and calculating a location of a fault by analyzing single-end traveling waves. The power delivery system 100 may include generation, transmission, distribution and/or similar power delivery systems. In the depicted embodiment, a two-terminal line of the power delivery system 100 is illustrated. For example, the two-terminal line may include line relays, such as a first line relay and a second line relay, disposed at each end of the two-terminal line. The power delivery system 100 may include intelligent electronic devices (IEDs) 102 and 104 (and/or other suitable sensors, such as electrical sensors or temperature sensors, and so forth) at the two relays of the power delivery system 100. In some embodiments, the power delivery system 100 may include additional IEDs (not shown), for example, to monitor other locations of the power delivery system 100.

The IEDs 102 and/or 104 may include a communication component, a processor, a memory, a storage, input/output (I/O) ports, a display, and the like. The communication component may facilitate communication between the IEDs 102 and/or 104 and any other suitable communication-enabled devices. The processor may be any suitable type of processor capable of executing computer-executable code. The processor may also include multiple processors that may perform the operations described below. The memory and the storage may be any suitable articles of manufacture that can serve as media to store processor-executable code, data, or the like. These articles of manufacture may represent computer-readable media (e.g., any suitable form of memory or storage) that may store the processor-executable code used by the processor to perform the presently disclosed techniques. The memory and the storage may store data, various other software applications for analyzing the data, and the like. The memory and the storage may represent non-transitory computer-readable media (e.g., any suitable form of memory or storage) that may store the processor-executable code used by the processor to perform various techniques described herein.

A data communication channel 106 may allow the IEDs 102 and 104 to exchange information relating to, among other things, voltages, currents, fault detections, fault locations, and the like. The IEDs 102 and 104 may also receive common time information from a common time source 108. The power delivery system 100 includes a conductor 110, such as a transmission line having a line length (LL). The conductor 110 may connect a local terminal 112 (L) (e.g., a first terminal, a first node) and a remote terminal 114 (R) (e.g., a second terminal, a second node) of the power delivery system 100. The local terminal 112 and the remote terminal 114 may be part of buses in the power delivery system 100 and may be supplied by generators 116 and 118, respectively. Although illustrated in single line form for purposes of simplicity, the power delivery system 100 may be a multi-phase system, such as a three-phase electrical power delivery system.

As used herein, an IED (such as IEDs 102 and 104) may refer to any viable processing circuitry including one or more processors, microprocessors, programable logic devices, field-programmable gate array, or any combination thereof, among other things. An IED may monitor, control, automate, and/or protect monitored equipment within the power delivery system 100. Such devices may include, for example, remote terminal units, differential relays, distance relays, directional relays, feeder relays, overcurrent relays, voltage regulator controls, voltage relays, breaker failure relays, generator relays, motor relays, automation controllers, bay controllers, meters, recloser controls, communications processors, computing platforms, programmable logic controllers (PLCs), programmable automation controllers, input and output modules, and the like. The term IED may be used to describe an individual IED or a system comprising multiple IEDs. For example, the IEDs 102 and 104 may obtain electric power system information using current transformers (CTs), potential transformers (PTs), Rogowski coils, voltage dividers and/or the like. The IEDs 102, 104 may be capable of using inputs from conventional instrument transformers such as current transformers, potential or voltage transformers conventionally used in monitoring power delivery systems.

The common time source 108 may be any time source capable of delivering a common time signal to each of IEDs 102 and 104. Some examples of a common time source include a Global Navigational Satellite System (GNSS) such as the Global Positioning System (GPS) delivering a time signal corresponding with IRIG (Inter-Range Instrumentation Group), a network-based system such as corresponding with Institute of Electrical and Electronics Engineers (IEEE) 1588 precision time protocol, and/or the like. According to one embodiment, the common time source 108 may comprise a satellite-synchronized clock (e.g., Model No. SEL-2407, available from SEL, among other possibilities). Further, it should be noted that each IED 102 and 104 may be in communication with a separate clock, such as a satellite-synchronized clock, with each clock providing each IED 102 and 104 with a common time signal. The common time signal may be derived from a GNSS system or other time signals.

According to some embodiments, a time signal based on the common time source 108 may be distributed to and/or between IEDs 102 and 104 using data communication channel 106. Data communication channel 106 may be embodied in a variety of media and may utilize a variety of communication protocols. For example, the data communication channel 106 may be embodied using physical media, such as coaxial cable, twisted pair, fiber optic, etc. The data communication channel 106 may utilize communication protocols such as Ethernet, Synchronous Optical Network (SONET), Synchronous Digital Hierarchy (SDH), or the like, in order to communicate data.

With the foregoing in mind, a fault may occur on the conductor 110 at a location (F) between the local terminal 112 and the remote terminal 114. The fault may cause generation of (e.g., propagate) one or more traveling waves, an impedance change, and/or a voltage magnitude change. The fault may include an open circuit, a partial open circuit, a short circuit, a partial short circuit, among other possibilities. In some embodiments, the IED 102 may determine and/or receive multiple potential fault locations associated with the location of the fault from the IED 102 along the conductor 110. Each potential fault location may be indicative of a potential location of the fault along the conductor 110 with respect to the local terminal 112. Moreover, the IED 102 may select, adjust, and/or sort the order of at least a portion of the potential fault locations by prioritizing the potential fault locations that more accurately indicate the fault location, as will be appreciated. As such, the IED 102 may select and/or determine one or more potential fault locations that indicate the location or position of the fault along the conductor 110 with improved accuracy.

The IED 102 may perform various operations based on determining and/or selecting the fault location. For example, the IED 102 may send control signals to various components of the power delivery system 100, switch on or off one or more components of the power delivery system 100, transmit an indication of the fault including the location, and/or the voltage magnitude change of the fault, among other possibilities. Although the IED 102 is described to determine and/or receive the potential fault locations, select and/or determine one or more potential fault locations with improved accuracy, and/or perform the operations, it should be appreciated that any other viable circuitry may perform the operations separately from or in-part with the IED 102. For example, the IED 102 may output at least a portion of the data, such as indications of received traveling waves, and/or determined and/or received potential fault locations, among other things, to any other viable circuitry. Moreover, any other viable circuitry may receive and/or determine the potential fault locations, adjust and/or sort the order of the potential fault locations, and/or select a potential fault location.

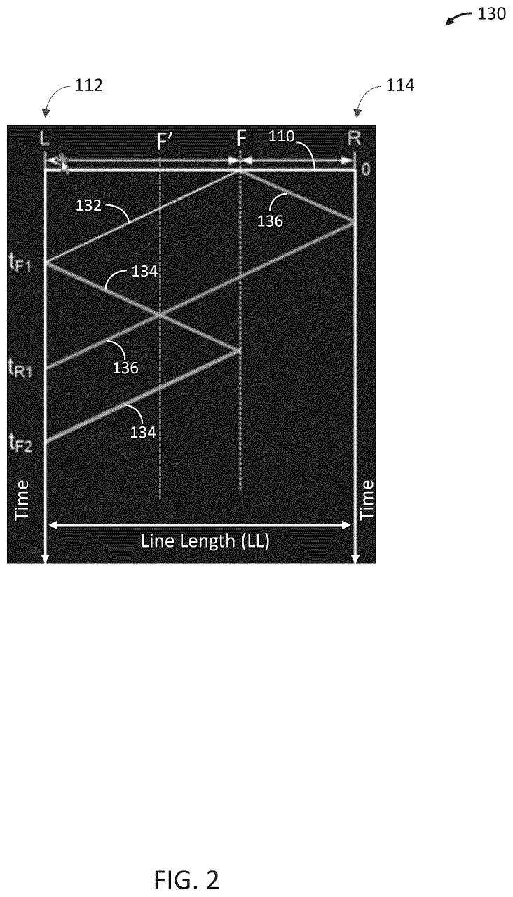

FIG. 2 is a plot 130 illustrating traveling waves 132, 134, and 136 associated with the fault on the conductor 110 received at the local terminal 112, according to embodiments of the current disclosure. The IED 102 and/or any other viable circuitry of the power delivery system 100 may receive and/or measure the traveling waves 132, 134, and 136 at and/or near the local terminal 112. In some embodiments, the traveling waves 132, 134, and 136 may be associated with one phase of a three phased power delivery system 100. The traveling waves 132, 134, and 136 may be indicative of electrical currents, alpha currents, and/or voltage levels across time.

In the depicted embodiment, the fault along the conductor 110 may cause propagation of the traveling waves 132, 134, and 136. For example, the fault may cause a change in characteristic impedance at the fault location (F) causing propagation and/or reflection of the traveling waves 132, 134, and 136. The IED 102 may receive the first traveling wave 132 directly from the fault location at a first time t_{F1}. The first traveling wave 132 may reflect off of the local terminal 112 and the fault location forming the second traveling wave 134. The IED 102 may receive the second traveling wave 134 at a second time t_{F2}. Moreover, a third traveling wave 136 may be propagated from the fault location to the remote terminal 114 and reflected off of the remote terminal 114. The IED 102 may receive the third traveling wave 136 from the remote terminal 114 at a third time t_{R1}. In some cases, the IED 102 may receive additional and/or alternative traveling waves propagated and/or reflected from the fault and/or the remote terminal 114, among other possibilities. The IED 102 may receive the traveling waves 132, 134, and 136 in any viable sequence.

The single end traveling wave fault location method may provide several potential fault locations based on the traveling waves 132, 134, and 136. In some embodiments, the IED 102 may determine and/or receive multiple potential fault locations and/or an estimated fault location based on the traveling waves 132, 134, and 136 and/or the impedance change. For example, the IED 102 may use any suitable form of single-end traveling wave fault location determination to identify the potential fault locations along the conductor 110. An example of single-end traveling wave fault location that may be used is described by U.S. Pat. No. 10,302,690, “Traveling Wave Based Single End Fault Location,” which is assigned to Schweitzer Engineering Laboratories Inc and incorporated by reference herein in its entirety for all purposes.

Moreover, the IED 102 may use any suitable form of single-end impedance fault location detection determination to estimate the fault location along the conductor 110 with respect to the local terminal 112 based on the impedance change. An example of the single-end impedance fault location detection that may be used is described by Schweitzer, O., III & Schweitzer Engineering Laboratories, Inc. (1993). A review of Impedance-Based Fault locating Experience (Revised),” which is assigned to Schweitzer Engineering Laboratories Inc and incorporated by reference herein in its entirety for all purposes. Alternatively or additionally, the IED 10 may receive the potential fault locations and/or the estimated fault location from any viable circuitry and/or component of the power delivery system 100.

In the depicted embodiment, the IED 102 may determine and/or receive a first potential fault location based on a time difference between the time t_{F1} for receiving the first traveling wave 132 and the time t_{F2} for receiving the second traveling wave 134. By way of example, the first potential fault location may be indicative of a distance from the local terminal 112 corresponding to the fault location (F). Moreover, the IED 102 may determine and/or receive a second potential fault location based on a time difference between the time t_{F1} for receiving the first traveling wave 132 and the time t_{R1} for receiving the third traveling wave 136. The second potential fault location may be indicative of a second distance from the local terminal 112 corresponding to an erroneous fault location (F′).

As mentioned above, the IED 102 may select, adjust, and/or sort the order of the first potential fault location and the second potential fault location. For example, the IED 102 may compare each potential fault location with the estimated fault location. Moreover, the IED 102 may determine that the first potential fault location is more closely aligned with the estimated fault location compared to the second potential fault location. Alternately or additionally, the first potential fault location may indicate a position of the fault with lower than a threshold difference compared to the estimated fault location. As such, the IED 102 may select and/or determine the first potential fault location over the second potential fault location. Accordingly, the IED 102 may indicate the location or position of the fault along the conductor 110 with improved accuracy.

It should be appreciated that in some cases, the second traveling wave 134 may reflect off of the local terminal 112 and the fault location forming additional traveling waves (not shown). The IED 102 may receive the additional traveling waves at respective times. Moreover, the IED 102 may determine and/or receive additional potential fault locations based on a time difference between the time t_{F1}, the time t_{F2}, among other possibilities, and the respective times for receiving the additional traveling waves. As mentioned above, the IED 102 may select, adjust, and/or sort the order of at least a portion of the potential fault locations by prioritizing the potential fault locations that more accurately indicate the fault location.

The IED 102 may compare each additional potential fault location with the estimated fault location. Moreover, the IED 102 may determine a potential fault location among the first potential fault location, the second potential fault location, and the additional potential fault locations aligned with the estimated fault location more closely. As such, the IED 102 may select and/or determine the potential fault location closely aligned (e.g., the most closely aligned, aligned) with the estimated fault location. For example, the selected potential fault location may indicate a position of the fault with lower than the threshold difference compared to the estimated fault location. Accordingly, the IED 102 may indicate the location or position of the fault along the conductor 110 with improved accuracy.

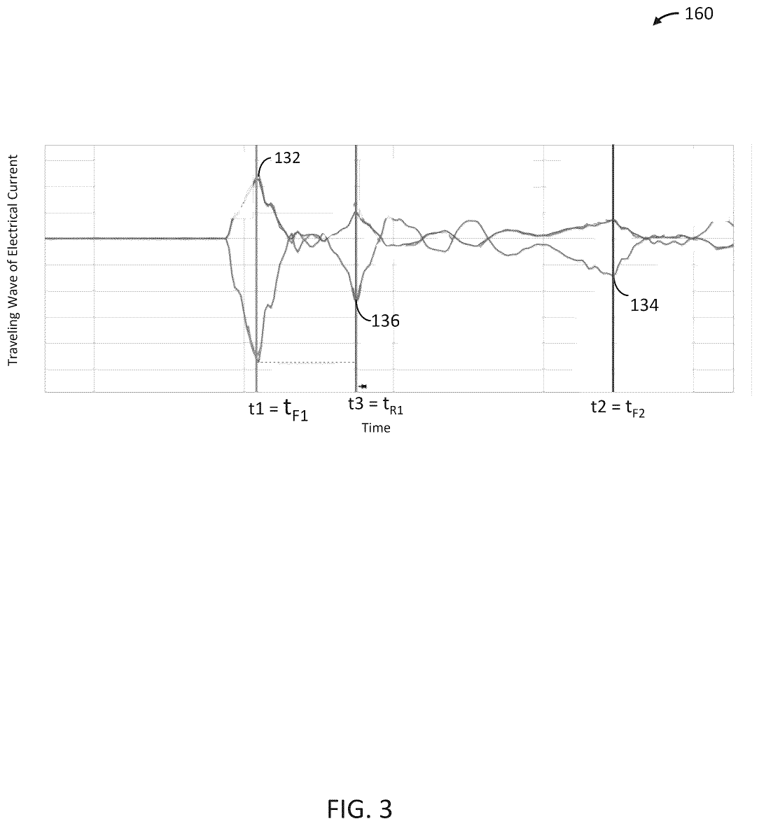

FIG. 3 is a plot 160 illustrating traveling waves 132, 134, and 136 of electrical currents (e.g., alpha currents) indicative of a location of the fault, according to embodiments of the current disclosure. As mentioned above, the fault may cause generation of (e.g., propagate) one or more traveling waves, an impedance change, and/or a voltage magnitude change. For example, the fault may cause a change in characteristic impedance at the fault location (F) causing propagation and/or reflection of the traveling waves 132, 134, and 136. Moreover, the IED 102 may determine and/or receive multiple potential fault locations and/or an estimated fault location based on the traveling waves 132, 134, and 136 and/or the characteristic impedance change.

The plot 160 illustrates the alpha quantities for a phase A, a phase B, and a phase C. t1 corresponds to an arrival time of the first traveling wave 132, t3 corresponds to an arrival time of the third traveling wave 136 reflected from the remote terminal 114. A time difference between t3 and t1 (e.g., t3-t1) may provide an erroneous potential fault location when the IED 102 uses the local terminal 112 as reference. The IED 102, may adjust this erroneous potential fault location by using the remote terminal 114 as reference and adjusting the calculations accordingly, as will be appreciated.

The IED 102 may determine and/or receive each potential fault location with a confidence level. A higher confidence level of a potential fault location may be indicative of a higher accuracy of the potential fault location for indicating the location of the fault along the conductor 110. In some cases, the IED 102 may adjust confidence levels of the potential fault locations. For example, the IED 102 may adjust confidence levels of the potential fault locations based on how closely each of the potential fault locations compare or align with a reference value such as the estimated fault location.

Alternatively or additionally, the IED 102 may order the potential fault locations based on an accuracy of indicating the fault location. For example, the potential fault locations with greater confidence levels (e.g., adjusted confidence levels) and/or least absolute difference values compared to the single-end impedance fault location and/or the line length may indicate the location of the fault with greater accuracy. As such, the IED 102 may order the potential fault locations by prioritizing the potential fault locations having the greatest confidence levels and/or the least absolute difference values.

In some embodiments, the IED 102 may select a potential fault location from the confidence adjusted and/or ordered potential fault locations to correspond to the location of the fault from the IED 102 along the conductor 110. For example, the IED 102 may exclude one or more potential fault locations with confidence levels equal to or below a confidence threshold. Among the remaining potential fault locations, the IED 102 may select a potential fault location having a greatest confidence level and/or select a potential fault location associated with a greatest voltage magnitude change. The IED 102 may indicate location or distance of the fault from the local terminal 112 based on a voltage magnitude and/or a voltage magnitude change associated with the traveling wave 132, 134, and/or 136 indicative of the selected potential fault location.

In the depicted embodiment, the IED 102 may determine the first potential fault location based on a first traveling wave 132 and/or magnitude change (e.g., voltage magnitude change) of the first traveling wave 132 and the second traveling wave 134 at a time t2. The first potential fault location may be indicative of the first distance from the local terminal 112 corresponding to the fault location (F) based on the time t2. Moreover, the IED 102 may determine the second potential fault location based on a second electrical current change and/or voltage magnitude change of the first traveling wave 132 and the third traveling wave 136 at a time t3. The second potential fault location may be indicative of the second distance from the local terminal 112 corresponding to the erroneous fault location (F′) based on the time t3.

By way of example, the second potential fault location may indicate a greater electrical current change and/or voltage magnitude change compared to the first potential fault location. If not accounted for, in some cases, an IED may select the erroneous fault location (F′) based on the greater electrical current change and/or voltage magnitude change associated with the second potential fault location compared to that associated with the first potential fault location. The IED 102 may adjust confidence levels of the first potential fault location and the second potential fault location and/or order the first potential fault location and the second potential fault location based on an accuracy of indicating the fault location. Accordingly, the IED 102 may select the first potential fault location indicative of the fault location (F) based on adjusting the confidence levels and/or ordering the first potential fault location and the second potential fault location.

In some embodiments, the IED 102 may send control signals to various components of the power delivery system 100, switch on or off one or more components of the power delivery system 100, transmit an indication of the fault including the location, the voltage magnitude, and/or the voltage magnitude of the fault, among other possibilities, based on determining and/or selecting a fault location. The IED 102 may adjust the confidence levels and/or sort the order of at least a portion of the potential fault locations to select the potential fault location accurately (e.g., more closely) corresponding to the fault location from the IED 102 along the conductor 110. As such, the selected potential fault location may indicate the location or position of the fault along the conductor 110 with improved accuracy.

Although the IED 102 is described to perform the operations, it should be appreciated that any other viable circuitry may perform the operations separately from or in-part with the IED 102. For example, the IED 102 may output at least a portion of the data, such as indications of received traveling waves, determined and/or received potential fault locations, determined and/or received confidence levels of the potential fault locations, determined and/or received estimated fault location, among other things, to any other viable circuitry. Moreover, any other viable circuitry receiving and/or determining the potential fault locations, the confidence levels of the potential fault locations, and/or the estimated fault location may adjust the confidence levels, sort the order of at least a portion of the potential fault locations, and/or select a potential fault location.

In a non-limiting example, the plot 160 illustrates traveling waves of the alpha currents for a fault on Phase A to ground with reflection from the remote terminal 114. The single end traveling wave fault location method may provide several possible fault locations. The order of the fault locations is from the most accurate to the least accurate fault location result. FIG. 3 shows current traveling waves on three phases A TW, B TW, and C TW for a fault on, for example, a 21.71 km, 69 kV power line. The traveling waves correspond to the alpha currents for the phase A-to-ground fault on the line as obtained from an event report captured when the fault occurred. The reflected traveling wave of the highest magnitude corresponds to the reflection from the remote terminal 114 and not from the local terminal 112. There may be several possible single end traveling wave fault locations determined based on this data using a single-end traveling wave fault location determination method. By way of example, of these possible values, the highest-confidence value initially generated may be provided as a distance of 4.787 km. FIG. 3 includes an indication of the first reflection from the remote terminal 114, which in this case is the fault location reported by the device. That is, the fault location value corresponds to the distance from the fault to the remote terminal 114. The actual fault location from the local terminal 112 is approximately at 16.923 km (21.71 km-4.787 km). It should be understood that the numbers are provided by the way of example and may be changed in different embodiments.

There are many instances where the reflected traveling wave with the highest magnitude is the traveling wave reflected from the remote terminal 114 and not from the local terminal 112. The methods of this disclosure select the local terminal 112 or the remote terminal 114 as the reference for the fault location based on the fault location reported by the single-end impedance fault location method.

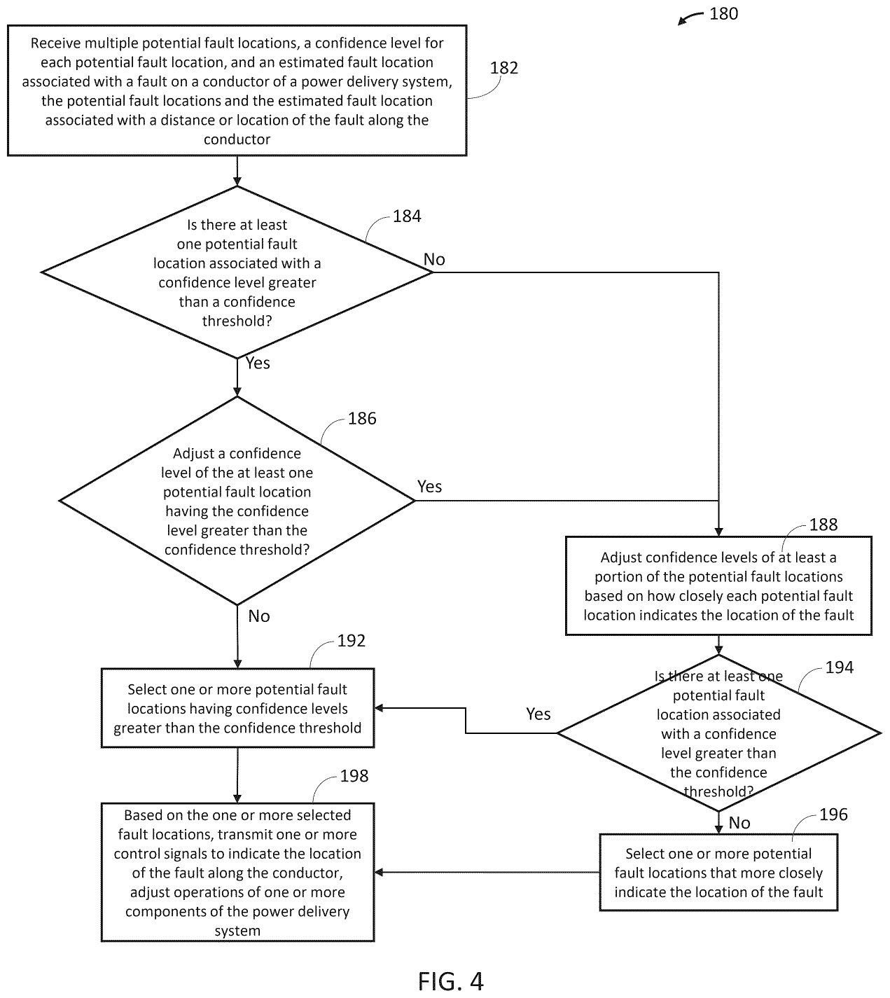

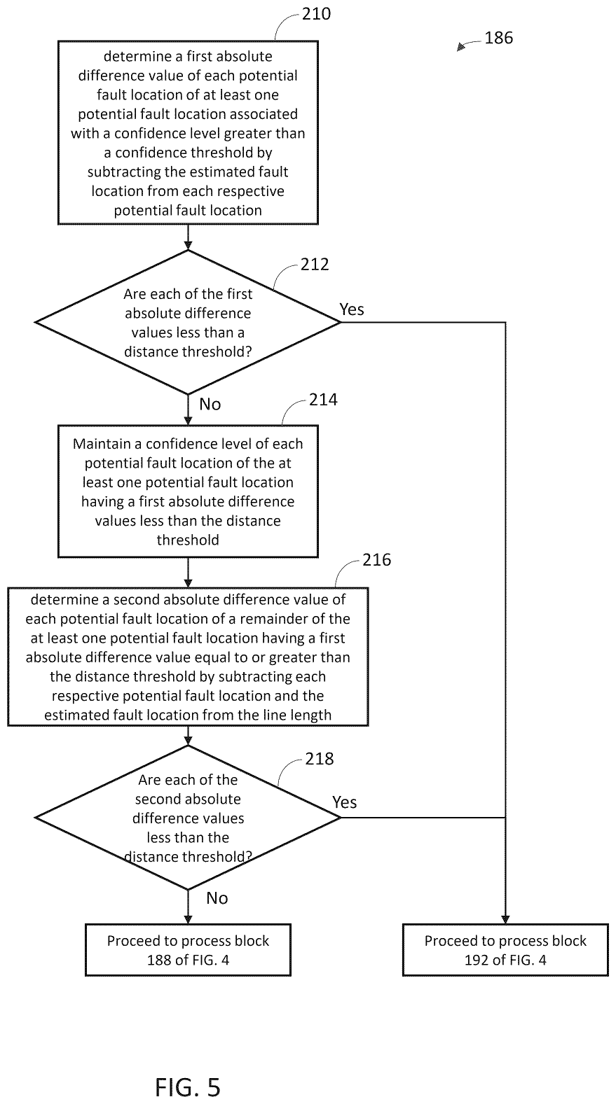

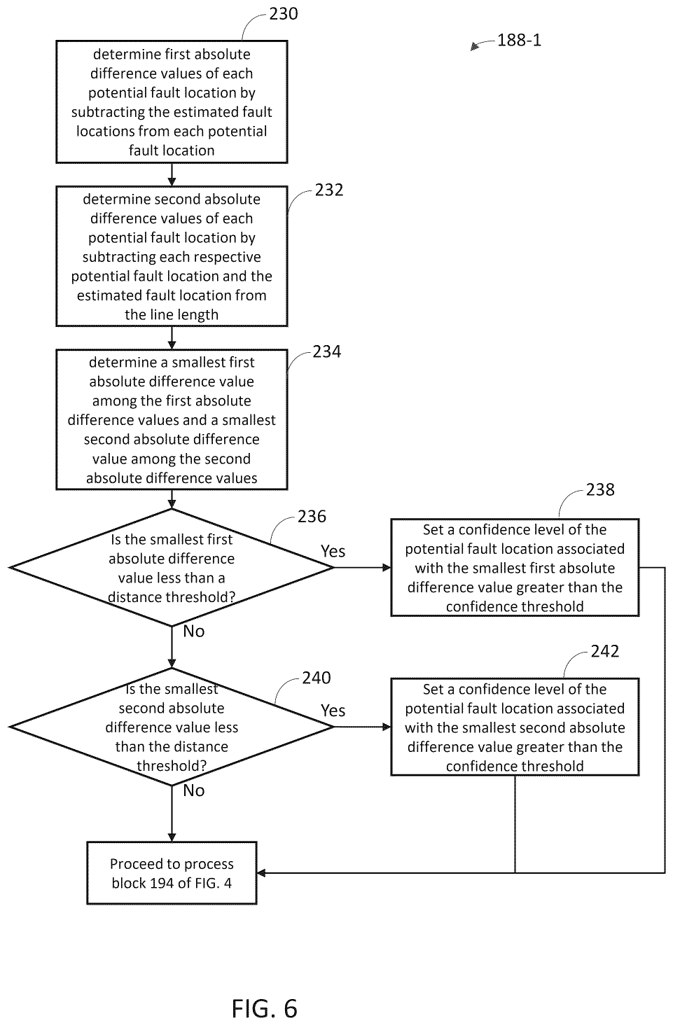

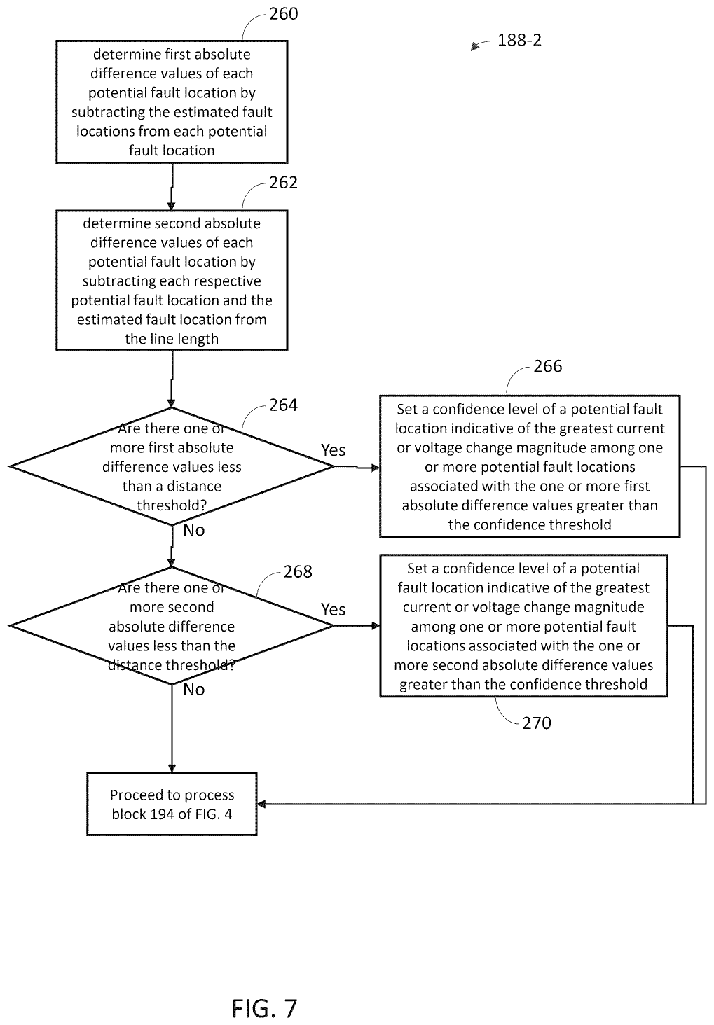

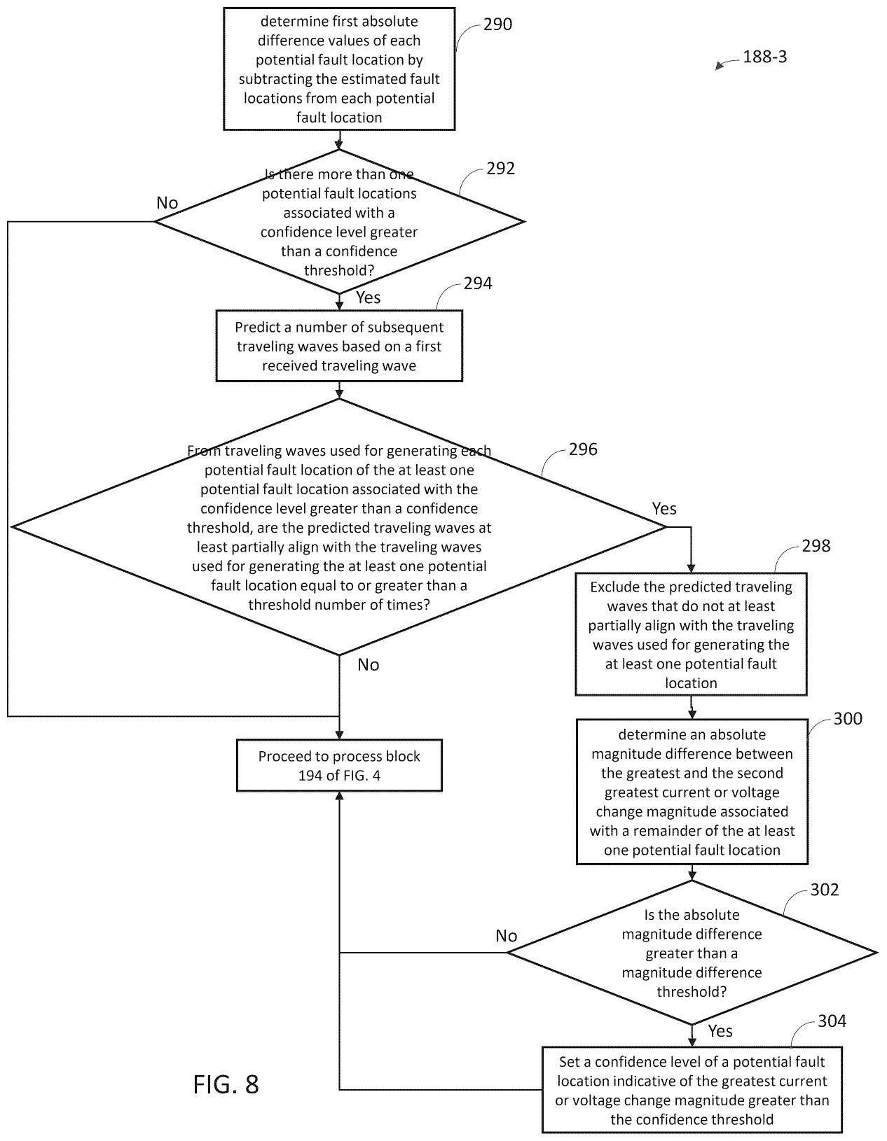

With the foregoing in mind, FIGS. 4-11 are flowcharts of methods for determining a confidence level and/or adjusting an order of the potential fault locations of a fault based on an estimated fault location, among other things. FIGS. 4-11 describe processes for considering the traveling wave reflections of the local terminal 112 or remote terminal 114 as reference based on the comparison of the potential fault locations resulting from the single-end traveling wave fault location method with the estimated fault location resulting from the single-end impedance fault location method.

Although the following description of processes 180, 186, 188-1, 188-2, 188-3, 330, 360, and 410 of FIGS. 4-11 are described with reference to the IED 102, it should be noted that these processes may be performed by any viable processing circuitry disposed on the IED 102 and/or other devices that may be capable of communicating with the IED 102, among other possibilities. Additionally, although the following processes 180, 186, 188-1, 188-2, 188-3, 330, 360, and 410 describe a number of operations that may be performed, it should be noted that each of the processes 180, 186, 188-1, 188-2, 188-3, 330, 360, and 410 may be performed in a variety of suitable orders and all of the operations may not be performed. It should be appreciated that the processes 180, 186, 188-1, 188-2, 188-3, 330, 360, and 410 may be wholly executed by the IED 102 or the execution may be distributed between the IED 102, the IED 104, and/or other circuitry.

FIG. 4 is a process flow diagram illustrating an embodiment of a process 180 of selecting one or more potential fault locations among multiple potential fault locations that more accurately indicate a fault location along the conductor 110 of the power delivery system 100, according to embodiments of the present disclosure. At block 182, the IED 102 may receive multiple potential fault locations, a confidence level associated with each potential fault location, and an estimated fault location of a fault. Each of the potential fault locations and the estimated fault location may be indicative of a distance or location of the fault along the conductor 110 from the IED 102 and/or the local terminal 112. The potential fault locations may have similar or different (e.g., varying) levels of confidence. Moreover, any suitable form of confidence level determination may be used to determine the confidence levels. It should be appreciated that in some embodiments, the IED 102 may determine (e.g., generate) the received potential fault locations, the confidence levels, and the estimated fault location.

The confidence levels may indicate an estimated accuracy for indicating the fault location. As mentioned above, a higher confidence level of a potential fault location may be indicative of a higher accuracy of the potential fault location. At block 184, the IED 102 may determine whether at least one potential fault location is associated with a confidence level greater than a confidence threshold (e.g., 0.5, 0.63, 1, 2, 2.68, 3, and so on, among other possibilities). The IED 102 may proceed to operations of block 186 when confidence levels of one or more potential fault locations are greater than the confidence threshold (e.g., a first confidence threshold). The IED 102 may proceed to operations of block 188 when confidence levels of the potential fault locations are equal to or less than the confidence threshold.

At block 186, the IED 102 may determine whether to adjust a confidence level of the at least one potential fault location having the confidence level greater than the confidence threshold. In some embodiments, the IED 102 may determine absolute difference values between each potential fault location (e.g., having the confidence level greater than the confidence threshold) and the estimated fault location. A potential fault location may indicate the fault location more closely when the respective absolute difference value is lower.

At block 186, in some cases, the IED 102 may proceed to operations of block 188 to adjust the confidence level of the at least one potential fault location. For example, in such cases, the at least one potential fault location does not indicate the fault location with sufficient accuracy based on a distance threshold (e.g., first distance threshold). Alternatively, the IED 102 may maintain the confidence level of the at least one potential fault location when proceeding to operations of block 192.

As mentioned above, at block 184, the IED 102 may proceed to operations of block 188 when confidence levels of the potential fault locations are equal to or less than the confidence threshold. At block 188, the IED 102 may adjust confidence levels of at least a portion of the potential fault locations based on how closely each potential fault location indicates the location of the fault. For example, the IED 102 may set (e.g., adjust) a value of the confidence levels of the at least one potential fault location to an adjusted value equal to or below the confidence threshold (e.g., to zero, among other possibilities).

By way of example, at block 188, the IED 102 may adjust the confidence levels based on an accuracy of each potential fault location of the portion of the potential fault locations for indicating the fault location along the conductor 110. In some cases, the IED 102 may adjust confidence levels of the portion of potential fault locations by prioritizing each potential fault location having a lower absolute difference value with the estimated fault location. The IED 102 may determine whether a potential fault location indicates a first distance measured between the fault and the local terminal 112 or indicates a second distance measured between the fault and the remote terminal 114. Since the IED 102 is disposed at or near the local terminal 112, the IED 102 may adjust the potential fault locations indicating the second distance measured between the fault and the remote terminal 114 to indicate the first distance measured between the fault and the local terminal 112. Moreover, the IED 102 may determine a difference value of a potential fault location by subtracting the estimated fault location, measured between the fault and the local terminal 112, from the respective potential fault location and determine an absolute value of the subtraction result (e.g., to determine an absolute difference value).

In alternative or additional cases, the IED 102 may adjust confidence levels of the portion of potential fault locations by predicting subsequent traveling waves (e.g., the traveling waves 134 and 136) based on a first traveling wave (e.g., the first traveling wave 132), and determining whether the predictions align with the received traveling waves. With reference to the plot 130 of FIG. 2, the IED 102 in some cases may determine that the third traveling wave 136 is reflected off of the remote terminal 114. For example, the IED 102 may exclude the third traveling wave 136 and/or one or more potential fault locations determined based on the third traveling wave 136 with the first traveling wave 132 instead of being determined based on the second traveling wave 134 with the first traveling wave 132. It should be appreciated that the IED 102 may use any other viable method to adjust confidence levels of at least a portion of the potential fault locations based on how closely each potential fault location indicates the location of the fault.

Referring back to FIG. 4, the IED 102 may proceed to operations of block 194. At block 194, the IED 102 may determine whether at least one potential fault location is associated with a confidence level greater than the confidence threshold. As mentioned above, the IED 102 may adjust the confidence levels of at least a portion of the potential fault locations at the block 188. As such, in some cases, at block 194, the IED 102 may determine that at least one potential fault location is associated with a confidence level greater than the confidence threshold. In such cases, the IED 102 may proceed to operations of block 192. Alternatively, the IED 102 may proceed to operations of block 196 when the potential fault locations are associated with confidence levels equal to or less than the confidence threshold.

As mentioned above, at block 186, the IED 102 may also proceed to operations of block 192 when a confidence level of the at least one potential fault location is greater than the confidence threshold and maintained (e.g., not adjusted). At block 192, the IED 102 may select one or more potential fault locations having confidence levels greater than the confidence threshold. For example, at block 192, the at least one potential fault location indicates the fault location with sufficient accuracy based on the distance threshold. The IED 102 may use a magnitude of each traveling wave associated with respective potential fault location having a confidence level higher than the confidence threshold to select among the one or more potential fault locations. For example, the IED 102 may select a potential fault location with the traveling wave magnitude (e.g., magnitude of the traveling waves discussed above with respect to FIG. 3). For example, the IED 102 may determine whether one or more potential fault locations having a confidence level higher than the confidence threshold based on the local terminal 112 being the reference or one or more potential fault locations having a confidence level higher than the confidence threshold based on the remote terminal 114 being the reference is more accurate. The IED 102 may determine the accuracy by comparing the traveling wave magnitudes of the potential fault locations.

In some cases, the IED 102 may select the one or more potential fault locations by excluding one or more potential fault locations with confidence levels equal to or below the confidence threshold. As such, the IED 102 may proceed to operations of block 198. At block 198, the IED 102 may transmit one or more control signals to indicate the location of the fault along the conductor, adjust operations of one or more components of the power delivery system based on (e.g., using) the one or more selected fault locations.

At block 196, the IED 102 may select one or more potential fault locations that more closely indicate the location of the fault. For example, at block 196, the at least one potential fault location does not indicate the fault location with sufficient accuracy based on the distance threshold. In some cases, the IED 102 may sort the order of at least a portion of the potential fault locations based on accuracy of at least a portion of the potential fault locations for indicating the fault location along the conductor 110. In such cases, the IED 102 may order the potential fault locations by prioritizing the potential fault locations having the greatest confidence levels and/or the least absolute difference values compared to the estimated fault location. As such, the IED 102 may select one or more potential fault locations having the greatest confidence levels and/or the least absolute difference values. In some cases, the IED 102 may select the one or more potential fault locations by excluding one or more potential fault locations with confidence levels equal to or below a confidence threshold (e.g., a second confidence threshold) and/or absolute difference values equal to or greater than a distance threshold (e.g., a second distance threshold).

Moreover, the IED 102 may proceed to operations of block 198 to transmit one or more control signals to indicate the location of the fault along the conductor, adjust operations of one or more components of the power delivery system based on (e.g., using) the one or more selected fault locations. Accordingly, the IED 102 may select and/or determine one or more potential fault locations that indicate the location or position of the fault along the conductor 110 with improved accuracy. Accordingly, the IED 102 may improve operations of the power delivery system 100 by performing operations of block 198 based on an improved accuracy for determining and/or indicating the fault location along the conductor 110. It should be appreciated that in some embodiments, the IED 102 may perform operations of blocks 184-198 for each potential fault location or each pair of potential fault location and confidence level separately, and may select the one or more potential fault locations potential fault locations at blocks 192 and/or 196 after completing operations of blocks 184-198 for all or a portion of the potential fault locations and/or pairs of potential fault locations and confidence levels.

FIG. 5 is a process flow diagram illustrating an embodiment of a process 186 of determining whether to adjust the confidence level of the at least one potential fault location having the confidence level greater than the confidence threshold, according to embodiments of the present disclosure. At block 210, the IED 102 may determine a first absolute difference value of each potential fault location of at least one potential fault location associated with a confidence level greater than a confidence threshold by subtracting the estimated fault location from each respective potential fault location. At block 212, the IED 102 may determine whether each of the first absolute difference values are less than a distance threshold. The IED 102 may proceed to operations of process blocks 192 and/or 198 of FIG. 4 discussed above when each of the first absolute difference values is less than a distance threshold. Alternatively, the IED 102 may proceed to operations of process block 214.

At block 214, the IED 102 may maintain a confidence level of each potential fault location of the at least one potential fault location having a first absolute difference values less than the distance threshold. At block 216, the IED 102 may determine a second absolute difference value of each potential fault location of a remainder of the at least one potential fault location having a first absolute difference values equal to or greater than the distance threshold by subtracting each respective potential fault location and the estimated fault location from the line length. At block 218, the IED 102 may determine whether each of the second absolute difference values are less than a distance threshold. The IED 102 may proceed to operations of process block 192 of FIG. 4 discussed above when each of the first absolute difference values is less than a distance threshold. Alternatively, the IED 102 may proceed to operations of process block 188 of FIG. 4 discussed above.

FIG. 6 is a process flow diagram illustrating an embodiment of a first process 188-1 of adjusting confidence levels of at least a portion of the potential fault locations based on whether the received traveling waves are reflected from the local terminal 112 or the remote terminal 114, according to embodiments of the present disclosure. At block 230, the IED 102 may determine first absolute difference values of each potential fault location by subtracting the estimated fault locations from each potential fault location. At block 232, the IED 102 may determine second absolute difference values of each potential fault location by subtracting each respective potential fault location and the estimated fault location from the line length. At block 234, the IED 102 may determine a smallest first absolute difference value among the first absolute difference values and a smallest second absolute difference value among the second absolute difference values.

At block 236, the IED 102 may determine whether the smallest first absolute difference value is less than a distance threshold. The IED 102 may proceed to operations of process block 238 when the smallest first absolute difference value is less than the distance threshold. At block 238, the IED 102 may set a confidence level of the potential fault location associated with the smallest first absolute difference value greater than the confidence threshold. Alternatively, the IED 102 may proceed to operations of process block 240.

At block 240, the IED 102 may determine whether the smallest second absolute difference value is less than a distance threshold. The IED 102 may proceed to operations of process block 242 when the smallest second absolute difference value is less than the distance threshold. At block 242, the IED 102 may set a confidence level of the potential fault location associated with the smallest second absolute difference value greater than the confidence threshold. Alternatively, the IED 102 may proceed to operations of process block 194 of FIG. 4 discussed above. For example, the IED 102 may proceed to select one or more potential fault locations having confidence levels greater than the confidence threshold.

FIG. 7 is a process flow diagram illustrating an embodiment of a second process 188-2 of adjusting confidence levels of at least a portion of the potential fault locations based on current or voltage change magnitudes associated with the potential fault locations, according to embodiments of the present disclosure. At block 260, the IED 102 may determine first absolute difference values of each potential fault location by subtracting the estimated fault locations from each potential fault location. At block 262, the IED 102 may determine second absolute difference values of each potential fault location by subtracting each respective potential fault location and the estimated fault location from the line length.

At block 264, the IED 102 may determine whether there are one or more first absolute difference values less than a distance threshold. The IED 102 may proceed to operations of block 266 when there are one or more first absolute difference values less than a distance threshold. At block 266, the IED 102 may set a confidence level of a potential fault location indicative of the greatest current or voltage change magnitude among one or more potential fault locations associated with the one or more first absolute difference values greater than the confidence threshold. Alternatively, the IED 102 may proceed to operations of block 268.

At block 268, the IED 102 may determine whether there are one or more second absolute difference values less than the distance threshold. The IED 102 may proceed to operations of block 270 when there are one or more second absolute difference values less than a distance threshold. At block 270, the IED 102 may set a confidence level of a potential fault location indicative of the greatest current or voltage change magnitude among one or more potential fault locations associated with the one or more second absolute difference values greater than the confidence threshold. Alternatively, the IED 102 may proceed to operations of process block 194 of FIG. 4 discussed above.

FIG. 8 is a process flow diagram illustrating an embodiment of a third process 188-3 of adjusting confidence levels of at least a portion of the potential fault locations based on predicting a number of subsequent traveling waves based on a first received traveling wave, according to embodiments of the present disclosure. At block 290, the IED 102 may determine first absolute difference values of each potential fault location by subtracting the estimated fault locations from each potential fault location.

At block 292, the IED 102 may determine whether there is more than one potential fault locations associated with a confidence level greater than a confidence threshold. If not, the IED 102 may proceed to operations of process block 194 of FIG. 4 discussed above. Alternatively, the IED 102 may proceed to operations of block 294. At block 294, the IED 102 may predict a number of subsequent traveling waves based on a first received traveling wave using any viable method. Alternatively, the IED 102 may receive the predictions from any viable circuitry.

At block 296, the IED 102 may determine whether there are the predicted traveling waves at least partially aligned with the traveling waves used for generating the at least one potential fault location equal to or greater than a threshold number of times. The IED 102 may use the traveling waves used for generating each potential fault location of the at least one potential fault location associated with the confidence level greater than a confidence threshold. If not, the IED 102 may proceed to operations of process block 194 of FIG. 4 discussed above. Alternatively, the IED 102 may proceed to operations of block 298.

At block 298, the IED 102 may exclude the predicted traveling waves that do not at least partially align with the traveling waves used for generating the at least one potential fault location. At block 300, the IED 102 may determine an absolute magnitude difference between the greatest and the second greatest current or voltage change magnitude associated with a remainder of the at least one potential fault location. At block 302, the IED 102 may determine whether the absolute magnitude difference greater is than a magnitude difference threshold. If not, the IED 102 may proceed to operations of process block 194 of FIG. 4 discussed above. Alternatively, the IED 102 may proceed to operations of block 304. At block 304, the IED 102 may set a confidence level of a potential fault location indicative of the greatest current or voltage change magnitude greater than the confidence threshold.

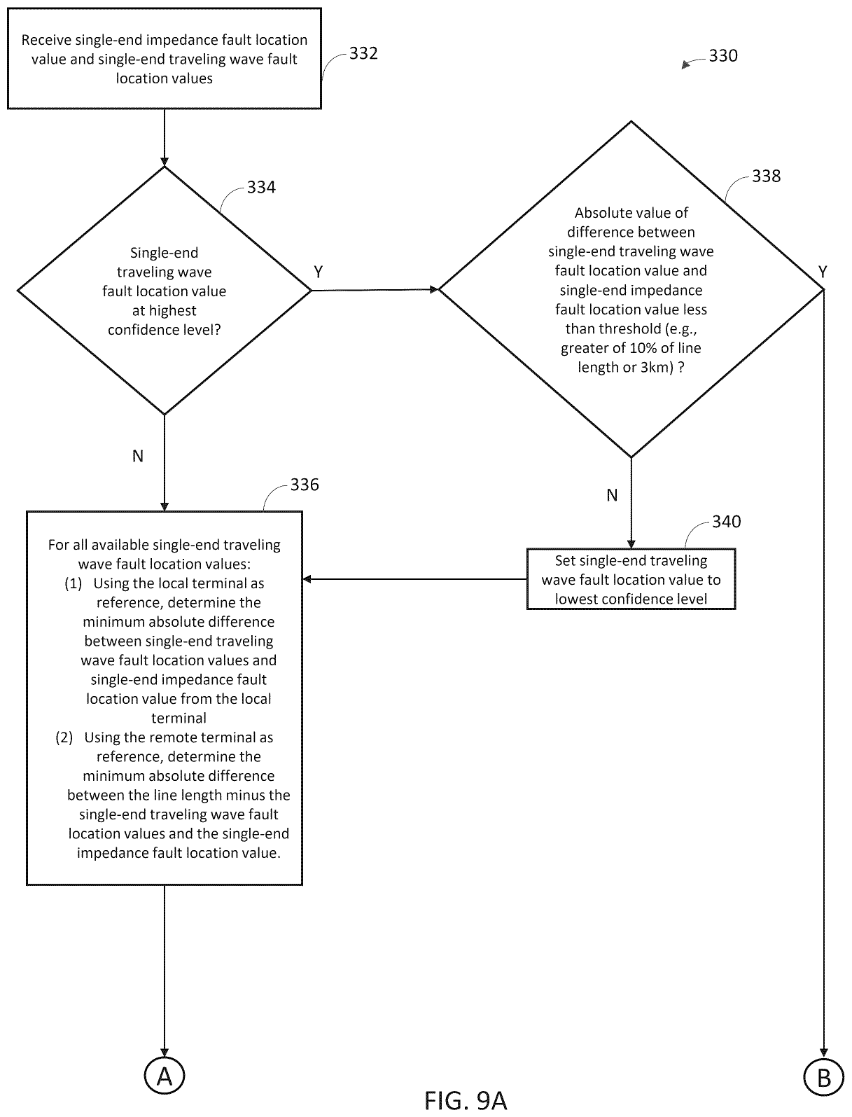

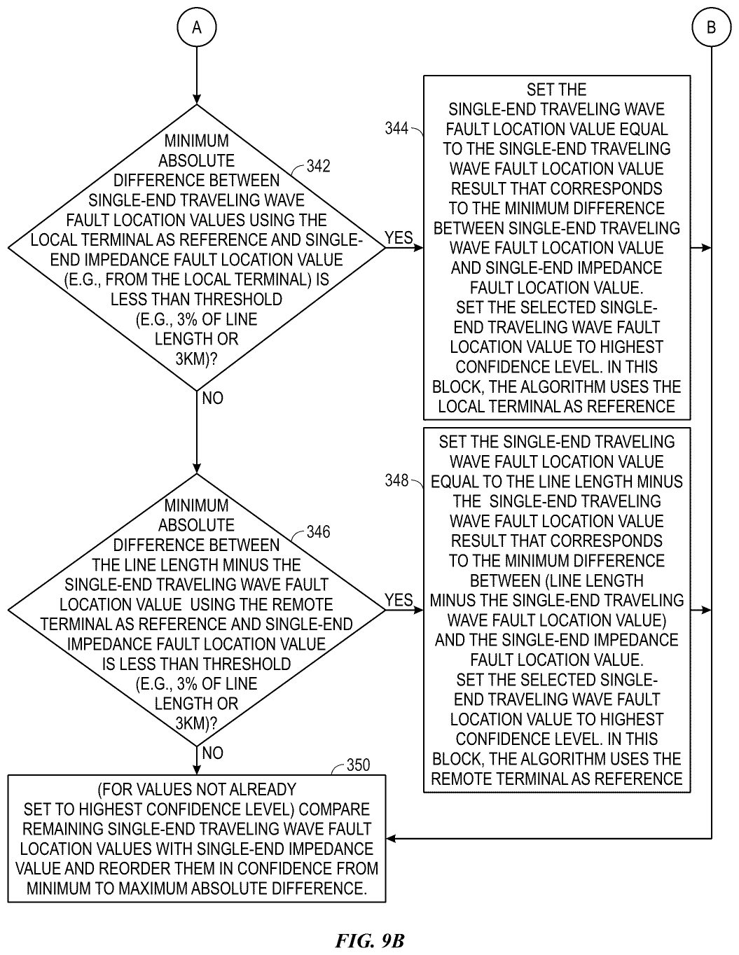

FIGS. 9A and 9B are a flowchart of a process 330 for determining a confidence level of single-end traveling wave fault location values, according to embodiments of the present disclosure. Each single-end traveling wave fault location value discussed herein may correspond to a respective potential fault location discussed above. Moreover, a single-end impedance fault location value may correspond to the estimated fault location discussed above.

At block 332, the IED 102 may receive single-end impedance fault location value and single-end traveling wave fault location values. At block 334, the IED 102 may determine whether a single-end traveling wave fault location value is at highest confidence level. At block 336, the IED 102, for all available single-end traveling wave fault location values, may determine the minimum absolute difference between single-end traveling wave fault location values and single-end impedance fault location value from the local terminal (e.g., using the local terminal as reference), and may determine the minimum absolute difference between the line length minus the single-end traveling wave fault location values and the single-end impedance fault location value (e.g., using the remote terminal as reference).

At block 338, the IED 102 may determine whether an absolute value of difference between single-end traveling wave fault location value and single-end impedance fault location value is less than threshold (e.g., greater of 10% of line length or 3 km). At block 340, the IED 102 may set single-end traveling wave fault location value to lowest confidence level. At block 342, the IED 102 may determine whether a minimum absolute difference between single-end traveling wave fault location values and single-end impedance fault location value (e.g., from the local terminal) is less than threshold (e.g., 3% of line length or 3 km).

At block 344, the IED 102 may set the single-end traveling wave fault location value equal to the single-end traveling wave fault location value result that corresponds to the minimum difference between single-end traveling wave fault location value and single-end impedance fault location value, and set the selected single-end traveling wave fault location value to highest confidence level. In this block, the algorithm uses the local terminal as reference. At block 346, the IED 102 may determine whether a minimum absolute difference between the line length minus the single-end traveling wave fault location value and single-end impedance fault location value is less than threshold (e.g., 3% of line length or 3 km).

At block 348, the IED 102 may set the single-end traveling wave fault location value equal to the line length minus the single-end traveling wave fault location value result that corresponds to the minimum difference between (line length minus the single-end traveling wave fault location value) and the single-end impedance fault location value, and set the selected single-end traveling wave fault location value to highest confidence level. In this block, the algorithm uses the remote terminal as reference. At block 350, the IED 102 may, for values not already set to highest confidence level, compare remaining single-end traveling wave fault location values with single-end impedance value and reorder them in confidence from minimum to maximum absolute difference.

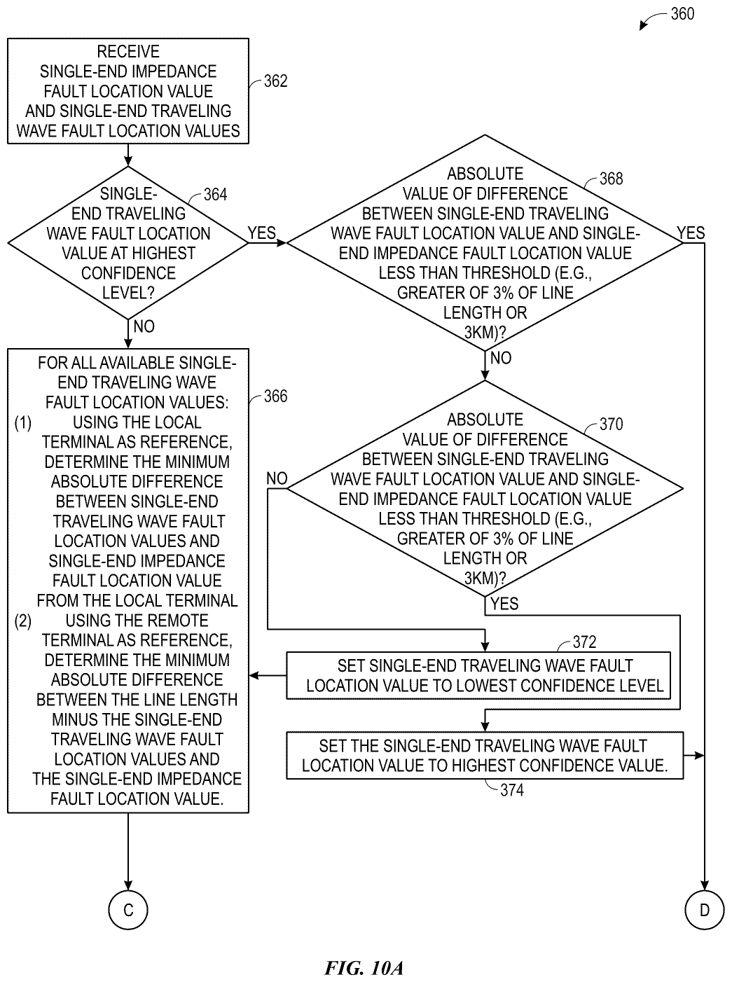

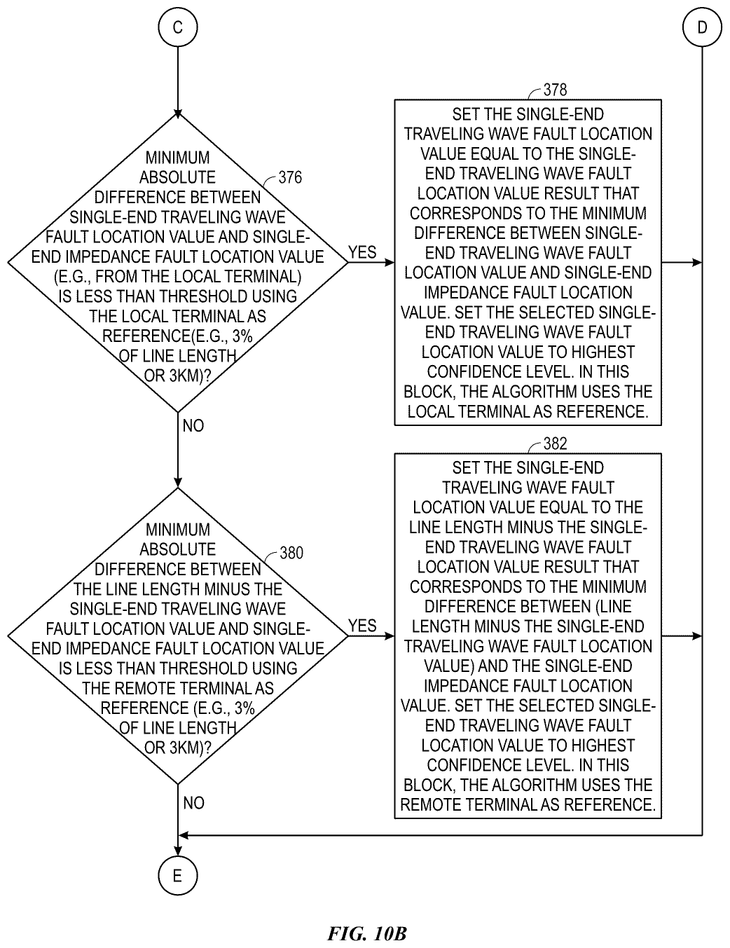

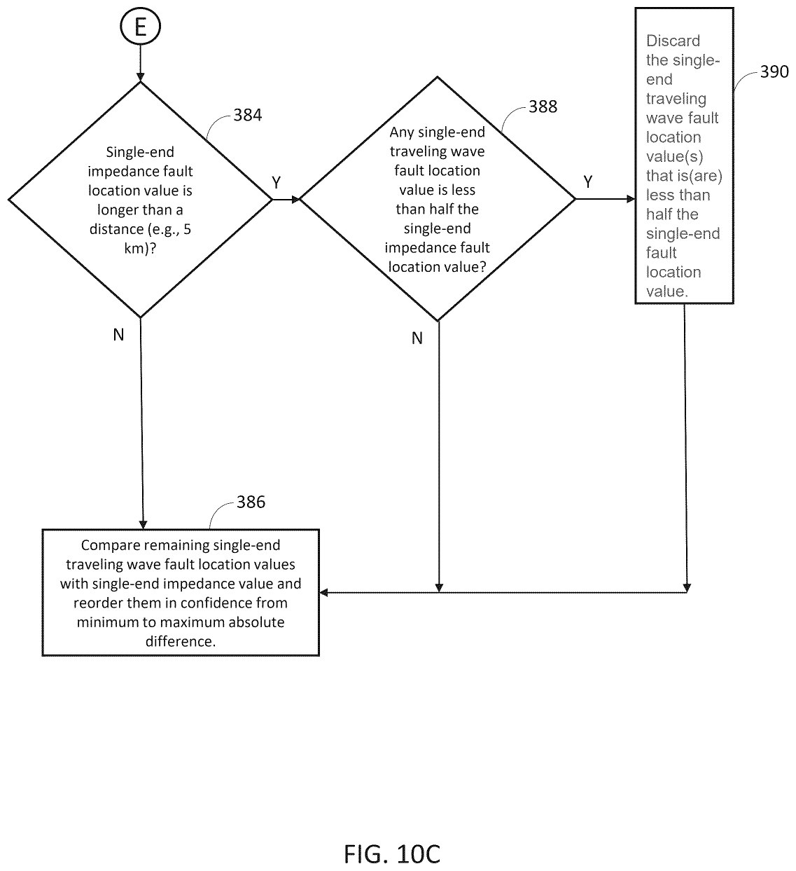

FIGS. 10A-10C are a flowchart of another process 360 for determining a confidence level of single-end traveling wave fault location values, according to embodiments of the present disclosure. At block 362, the IED 102 may receive the single-end impedance fault location value and the single-end traveling wave fault location values. At block 364, the IED 102 may determine whether a single-end traveling wave fault location value is at highest confidence level. At block 366, the IED 102 may for all available single-end traveling wave fault location values, determine the minimum difference between single-end traveling wave fault location values and single-end impedance fault location value from the local terminal using the local terminal as reference, and determine the minimum absolute difference between the line length minus the single-end traveling wave fault location values and the single-end impedance fault location value using the remote terminal as reference.

At block 368, the IED 102 may determine whether an absolute value of difference between single-end traveling wave fault location value and single-end impedance fault location value is less than threshold (e.g., greater of 3% of line length or 3 km). At block 370, the IED 102 may determine whether an absolute value of difference between (the line length minus the single-end traveling wave fault location value) and the single-end impedance fault location value is less than threshold (e.g., greater of 3% of line length or 3 km).

At block 372, the IED 102 may set single-end traveling wave fault location value to lowest confidence level. At block 374, the IED 102 may set single-end traveling wave fault location value equal to the difference between the line length and the single-end traveling wave fault location value. Also set the single-end traveling wave fault location value to highest confidence value. At block 376, the IED 102 may determine whether a minimum absolute difference between single-end traveling wave fault location value and single-end impedance fault location value (e.g., from the local terminal) is less than threshold (e.g., 3% of line length or 3 km).

At block 378, the IED 102 may set the single-end traveling wave fault location value equal to the single-end traveling wave fault location value result that corresponds to the minimum difference between single-end traveling wave fault location value and single-end impedance fault location value, and set the selected single-end traveling wave fault location value to highest confidence level. In this block, the algorithm uses the local terminal as reference. At block 380, the IED 102 may determine whether a minimum absolute difference between the line length minus the single-end traveling wave fault location value and single-end impedance fault location value is less than threshold (e.g., 3% of line length or 3 km).

At block 382, the IED 102 may set the single-end traveling wave fault location value equal to the line length minus the single-end traveling wave fault location value result that corresponds to the minimum difference between (line length minus the single-end traveling wave fault location value) and the single-end impedance fault location value, and set the selected single-end traveling wave fault location value to highest confidence level. In this block, the algorithm uses the remote terminal as reference.

At block 384, the IED 102 may determine whether the single-end impedance fault location value is longer than a distance (e.g., 5 km). At block 386, the IED 102 may compare remaining single-end traveling wave fault location values with single-end impedance value and reorder them in confidence from minimum to maximum absolute difference. At block 388, the IED 102 may determine whether any single-end traveling wave fault location value is less than half the single-end impedance fault location value. At block 390, the IED 102 may discard the single-end traveling wave fault location value(s) that is (are) less than half the single-end fault location value.

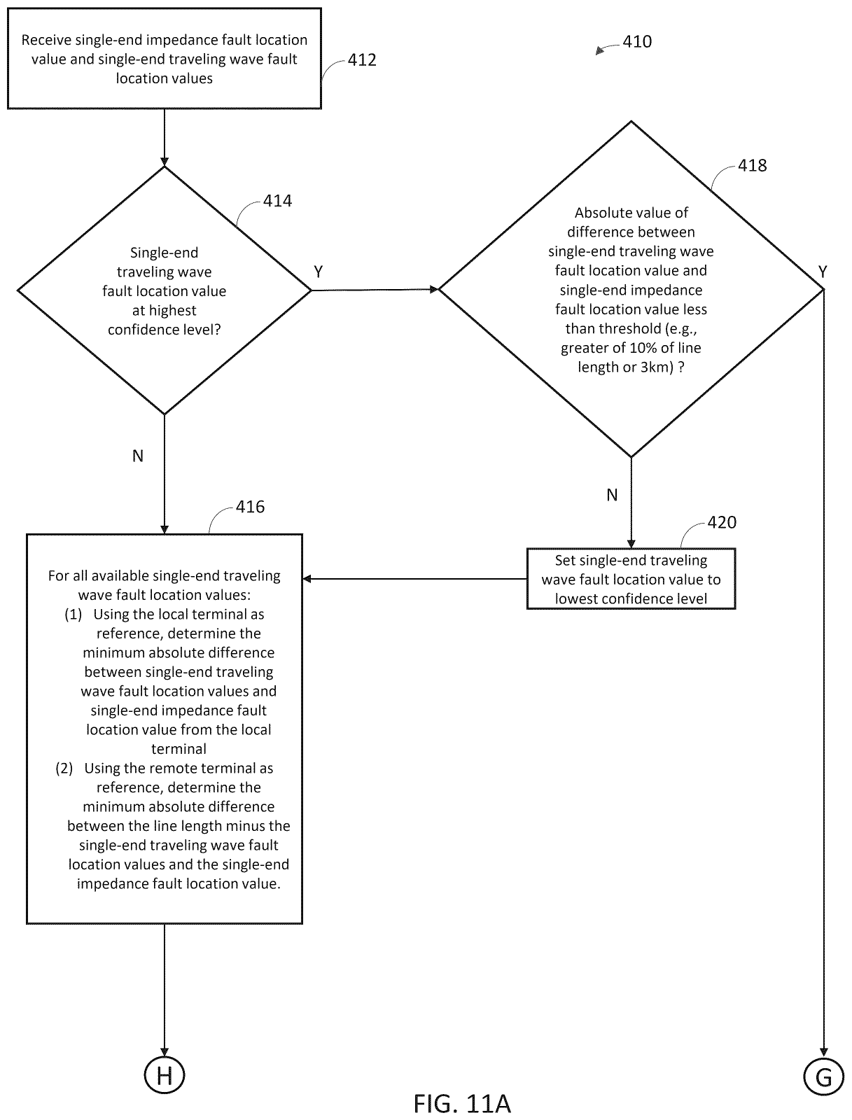

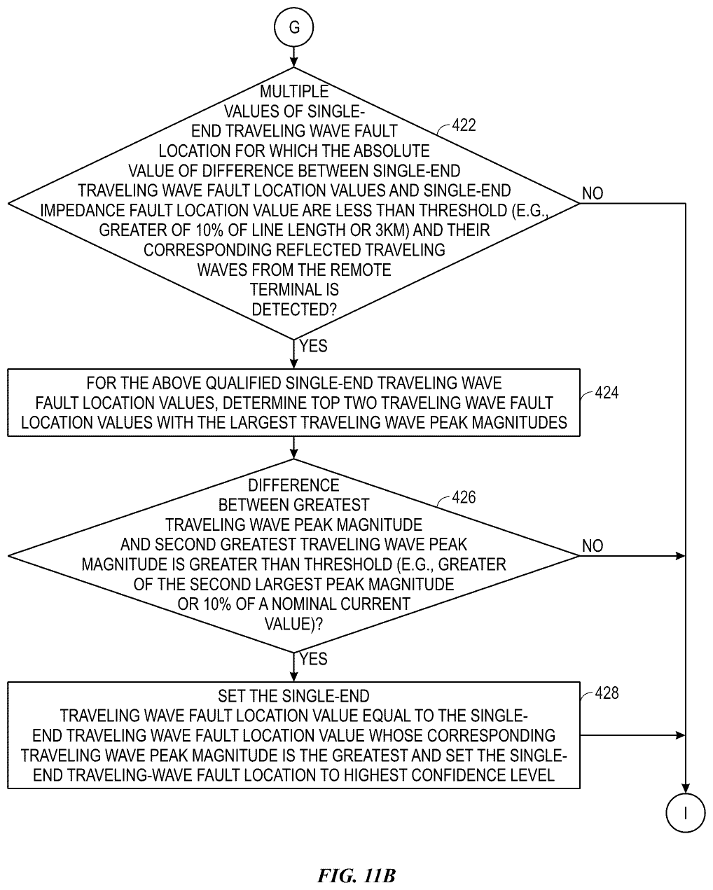

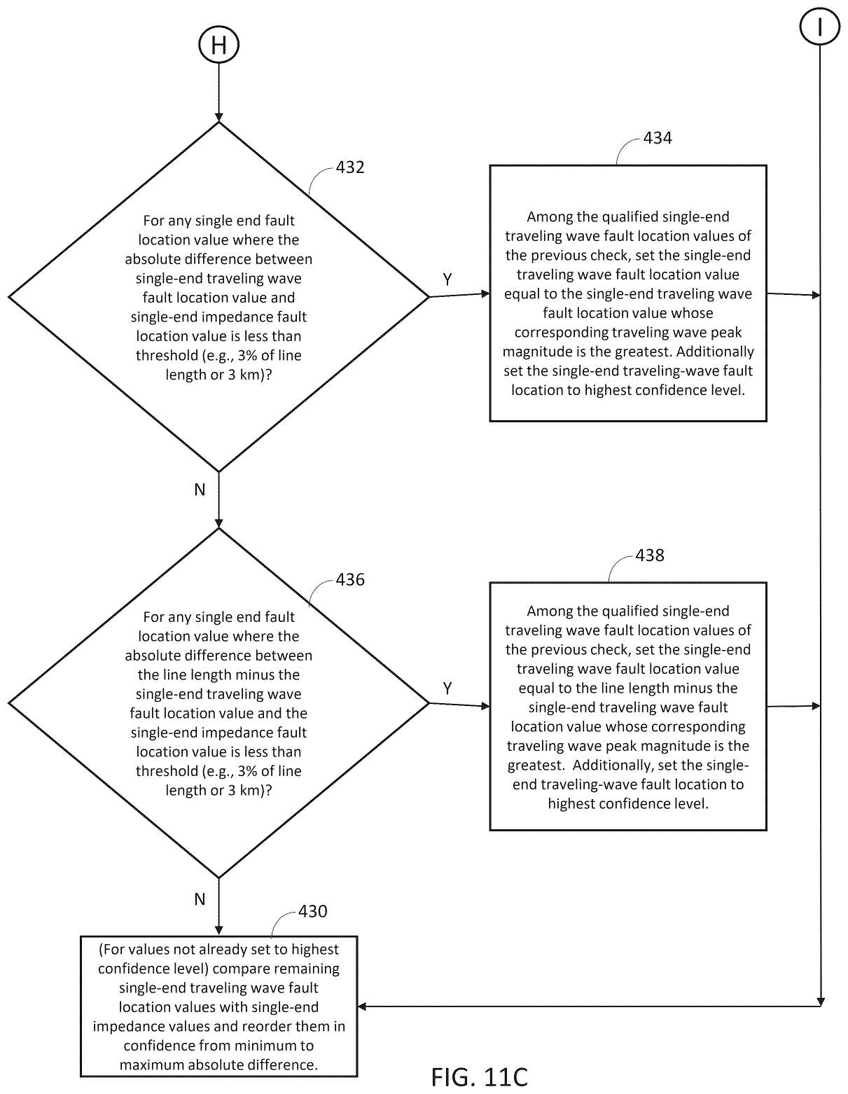

FIGS. 11A-11C are a flowchart of another process 410 for determining a confidence level of single-end traveling wave fault location values, according to embodiments of the present disclosure. At block 412, the IED 102 may receive single-end impedance fault location value and single-end traveling wave fault location values. At block 414, the IED 102 may determine whether the single-end traveling wave fault location value is at highest confidence level.

At block 416, the IED 102 may, for all available single-end traveling wave fault location values, determine the minimum absolute difference between single-end traveling wave fault location values and single-end impedance fault location value from the local terminal using the local terminal as reference, and determine the minimum absolute difference between the line length minus the single-end traveling wave fault location values and the single-end impedance fault location value using the remote terminal as reference.

At block 418, the IED 102 may determine whether an absolute value of difference between single-end traveling wave fault location value and single-end impedance fault location value less than threshold (e.g., greater of 10% of line length or 3 km). At block 420, the IED 102 may set single-end traveling wave fault location value to lowest confidence level. At block 422, the IED 102 may determine whether multiple values of single-end traveling wave fault location for which the absolute value of difference between single-end traveling wave fault location values and single-end impedance fault location value are less than threshold (e.g., greater of 10% of line length or 3 km) and whether the corresponding reflected traveling waves from the remote terminal are detected. At block 424, the IED 102 may, for the above qualified single-end traveling wave fault location values, determine top two fault location values with the largest traveling wave peak magnitudes (e.g., largest traveling wave peak amplitudes).

At block 426, the IED 102 may determine whether a difference between greatest traveling wave peak magnitude (e.g., a peak voltage magnitude of the traveling wave) and second greatest traveling wave peak magnitude is greater than threshold (e.g., greater of the second largest peak magnitude or 10% of a nominal current value). At block 428, the IED 102 may set the single-end traveling wave fault location value equal to the single-end traveling wave fault location value whose corresponding traveling wave peak magnitude is the greatest and set the single-end traveling-wave fault location to highest confidence level. At block 430, the IED 102 may, for values not already set to highest confidence level, compare remaining single-end traveling wave fault location values with single-end impedance values and reorder them in confidence from minimum to maximum absolute difference.

At block 432, the IED 102 may determine whether for any single end fault location value where the absolute difference between single-end traveling wave fault location value and single-end impedance fault location value is less than threshold (e.g., 3% of line length or 3 km). At block 434, the IED 102 may, among the qualified single-end traveling wave fault location values of the previous check, set the single-end traveling wave fault location value equal to the single-end traveling wave fault location value whose corresponding traveling wave peak magnitude is the greatest. Additionally set the single-end traveling-wave fault location to highest confidence level.

At block 436, the IED 102 may determine whether for any single end fault location value where the absolute difference between the line length minus the single-end traveling wave fault location value and the single-end impedance fault location value is less than threshold (e.g., 3% of line length or 3 km). At block 438, the IED 102 may, among the qualified single-end traveling wave fault location values of the previous check, set the single-end traveling wave fault location value equal to the line length minus the single-end traveling wave fault location value whose corresponding traveling wave peak magnitude is the greatest. Additionally, set the single-end traveling-wave fault location to highest confidence level.

While specific embodiments and applications of the disclosure have been illustrated and described, it is to be understood that the disclosure is not limited to the precise configurations and components disclosed herein. For example, the systems and methods described herein may be applied to an industrial electric power delivery system or an electric power delivery system implemented in a boat or oil platform that may or may not include long-distance transmission of high-voltage power. Accordingly, many changes may be made to the details of the above-described embodiments without departing from the underlying principles of this disclosure. The scope of the present disclosure should, therefore, be determined only by the following claims.

Indeed, the embodiments set forth in the present disclosure may be susceptible to various modifications and alternative forms, specific embodiments have been shown by way of example in the drawings and have been described in detail herein. However, it may be understood that the disclosure is not intended to be limited to the particular forms disclosed. The disclosure is to cover all modifications, equivalents, and alternatives falling within the spirit and scope of the disclosure as defined by the following appended claims. In addition, the techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). For any claims containing elements designated in any other manner, however, it is intended that such elements are not to be interpreted under 35 U.S.C. 112(f).

1. Tangible, non-transitory, computer-readable media storing instructions that, when executed by processing circuitry of a local terminal of a power delivery system, cause the processing circuitry to:
receive a potential fault location and an estimated fault location associated with a fault location on a conductor of the power delivery system, wherein the conductor is coupled to the local terminal and a remote terminal of the power delivery system;
determine whether the potential fault location indicates a distance between the fault location and the remote terminal;
adjust the potential fault location to a difference value between a line length of the conductor and the potential fault location based on the potential fault location indicating the distance between the fault location and the remote terminal;
select the adjusted potential fault location based on a first absolute difference value between the adjusted potential fault location and the estimated fault location being less than a first distance threshold; and
transmit one or more control signals to indicate the selected potential fault location along the conductor.

2. The tangible, non-transitory, computer-readable media of claim 1, wherein the instructions cause the processing circuitry to select the potential fault location based on the potential fault location indicating a distance between the fault location and the local terminal and a second absolute difference value between the potential fault location and the estimated fault location associated with the fault location being less than the first distance threshold.

3. The tangible, non-transitory, computer-readable media of claim 1, wherein the instructions cause the processing circuitry to receive a confidence level associated with the potential fault location, determine whether the confidence level is greater than a first confidence threshold, and determine whether the potential fault location indicates the distance between the fault location and the remote terminal based on the confidence level being equal to or less than the first confidence threshold.

4. The tangible, non-transitory, computer-readable media of claim 3, wherein the instructions cause the processing circuitry to, based on the confidence level being higher than the first confidence threshold and the potential fault location indicating the distance between the fault location and the remote terminal,
determine whether the first absolute difference value is equal to or less than a second distance threshold,
adjust the potential fault location to the difference value based on the first absolute difference value being greater than the second distance threshold, and
select the adjusted potential fault location.

5. The tangible, non-transitory, computer-readable media of claim 3, wherein the instructions cause the processing circuitry to, based on the confidence level being higher than the first confidence threshold and the potential fault location indicating the distance between the fault location and the local terminal,
determine whether the first absolute difference value is equal to or less than a second distance threshold, and
select the potential fault location based on the first absolute difference value being less than the second distance threshold.

6. The tangible, non-transitory, computer-readable media of claim 1, wherein the instructions cause the processing circuitry to:
receive an additional potential fault location, wherein the potential fault location is based on a first received traveling wave and the additional potential fault location is based on a second received traveling wave;
determine whether the additional potential fault location indicates a distance between the fault location and the remote terminal;
adjust the additional potential fault location to an additional difference value between the line length and the additional potential fault location based on the additional potential fault location indicating the distance between the fault location and the remote terminal;
select the adjusted additional potential fault location in lieu of the adjusted potential fault location based on an additional absolute difference value between the adjusted additional potential fault location being less than the first distance threshold and a second current or voltage magnitude of the second received traveling wave associated with the additional difference value being greater than a first current or voltage magnitude of the first received traveling wave; and
transmit the one or more control signals to indicate the selected potential fault location along the conductor.

7. The tangible, non-transitory, computer-readable media of claim 1, wherein the instructions cause the processing circuitry to:
receive an additional potential fault location, wherein the potential fault location is based on a first received traveling wave and the additional potential fault location is based on a second received traveling wave;
determine that the additional potential fault location indicates a distance between the fault location and the local terminal;
select the additional potential fault location in lieu of the potential fault location based on an additional absolute difference value between the additional potential fault location and the estimated fault location being less than the first absolute difference value; and
transmit the one or more control signals to indicate the selected potential fault location along the conductor.

8. The tangible, non-transitory, computer-readable media of claim 1, wherein the instructions cause the processing circuitry to adjust operations of one or more components of the power delivery system based on the selected potential fault location.

9. A power delivery system comprising:
a local terminal;
a conductor coupled to the local terminal and a remote terminal; and
processing circuitry associated with the local terminal and coupled to the conductor, wherein the processing circuitry is configured to:
receive a potential fault location and an estimated fault location associated with a fault location on the conductor of the power delivery system, wherein the conductor is coupled to the local terminal and a remote terminal of the power delivery system;
determine whether the potential fault location indicates a distance between the fault location and the remote terminal;
adjust the potential fault location to a difference value between a line length of the conductor and the potential fault location based on the potential fault location indicating the distance between the fault location and the remote terminal;
select the adjusted potential fault location based on a first absolute difference value between the adjusted potential fault location and the estimated fault location being less than a first distance threshold; and
transmit one or more control signals to indicate the selected potential fault location along the conductor.

10. The power delivery system of claim 9, wherein the processing circuitry is configured to receive a plurality of traveling waves initiated from the fault location, and generate the potential fault location based on the traveling waves.

11. The power delivery system of claim 9, wherein the potential fault location is determined based on a single end traveling wave fault location method.

12. The power delivery system of claim 9, wherein the processing circuitry is configured to select the potential fault location based on the potential fault location indicating a distance between the fault location and the local terminal and a second absolute difference value between the potential fault location and an estimated fault location associated with the fault location being less than the first distance threshold.

13. The power delivery system of claim 9, wherein the processing circuitry is configured to receive a confidence level associated with the potential fault location, determine whether the confidence level is greater than a first confidence threshold, and determine whether the potential fault location indicates the distance between the fault location and the remote terminal based on the confidence level being equal to or less than the first confidence threshold.

14. The power delivery system of claim 13, wherein the processing circuitry is configured to select the potential fault location based on the confidence level being higher than the first confidence threshold

15. The power delivery system of claim 13, wherein the processing circuitry is configured to, based on the confidence level being higher than the first confidence threshold and the potential fault location indicating the distance between the fault location and the remote terminal,
determine whether the first absolute difference value is equal to or less than a second distance threshold,
adjust the potential fault location to the difference value based on the first absolute difference value being greater than a second distance threshold, and
select the adjusted potential fault location.

16. The power delivery system of claim 13, wherein the processing circuitry is configured to, based on the confidence level being higher than the first confidence threshold and the potential fault location indicating the distance between the fault location and the local terminal, determine whether the first absolute difference value is equal to or less than a second distance threshold, and select the potential fault location based on the second absolute difference value being equal to or less than the second distance threshold.

17. A method comprising:
receiving, by processing circuitry of a power delivery system, a potential fault location and an estimated fault location associated with a fault location on a conductor of a power delivery system, wherein the conductor is coupled to a local terminal and a remote terminal of the power delivery system;
determining, by the processing circuitry, that the potential fault location indicates a distance between the fault location and the remote terminal;
adjusting, by the processing circuitry, the potential fault location to a difference value between a line length of the conductor and the potential fault location based on the potential fault location indicating the distance between the fault location and the remote terminal;
selecting, by the processing circuitry, the adjusted potential fault location based on an absolute difference value between the adjusted potential fault location and the estimated fault location being less than a first distance threshold; and
transmitting, by the processing circuitry, one or more control signals to indicate the selected potential fault location along the conductor.

18. The method of claim 17, comprising receiving, by the processing circuitry, a confidence level associated with the potential fault location.

19. The method of claim 18, determining, by the processing circuitry, that the potential fault location indicates the distance between the fault location and the remote terminal in response to the confidence level being equal to or less than a first confidence threshold.

20. The method of claim 17, comprising adjusting, by the processing circuitry, operations of one or more components of the power delivery system based on the selected potential fault location.
